(19) United States
(12) Patent Application Publication
(10) Pub. No.: US 2016/0238906 A1
(43) Pub. Date: Aug. 18, 2016

(54) TFT ARRAY SUBSTRATE STRUCTURE

(71) Applicant: SHENZHEN CHINA STAR OPTOELECTRONICS TECHNOLOGY CO., LTD., Guangdong (CN)

(72) Inventors: Chuan WU, Shenzhen, Guangdong (CN); Shihhsun LO, Shenzhen, Guangdong (CN)

(73) Assignee: Shenzhen China Star Optoelectronics Technology Co., Ltd., Shenzhen, Guangdong (CN)

(21) Appl. No.: 14/381,987

(22) PCT Filed: Jul. 18, 2014
(86) PCT No.: PCT/CN2014/082502

§ 371 Date: Aug. 28, 2014

(30) Foreign Application Priority Data
Jun. 17, 2014 (CN) 201410271512.1

(51) Int. Cl. G02F 1/1343; H01L 27/12; G02F 1/1368; G02F 1/1335; G02F 1/1362

(52) U.S. Cl. CPC G02F 1/134336; G02F 1/133514; G02F 1/133512; G02F 1/136286; G02F 1/1368; G02F 1/13439; H01L 27/124; G02F 2001/134345; G02F 2201/56

(57) ABSTRACT

The present invention provides a TFT (Thin-Film Transistor) array substrate structure, which includes a plurality of sub-pixels (4) arranged to correspond to a black matrix (2). Each of the sub-pixels (4) includes a main zone (42) and a sub zone (44). A data line (6) is arranged between the sub-pixels and a gate scan line (8) is arranged between the main zones (42) and the sub zones (44). Pixel electrode trunks (10) are arranged between two sub-pixels (4) and pixel electrode branches (12) are respectively set in the main zones (42) and the sub zones (44) of the two sub-pixels (4). The pixel electrode branches (12) are respectively in electrical connection with the pixel electrode trunks (10). When the TFT array substrate structure undergoes a relative displacement during a process of curving a liquid crystal display panel, the pixel electrode trunk (10) is still kept within an area covered by the black matrix so that an influence on an electric field is extremely small to thereby effectively improve electric characteristics, prevent the occurrence of dark patterns, and thus enhance the quality of the liquid crystal display panel.

### BACKGROUND OF THE INVENTION

1. Field of the Invention

The present invention relates to the field of liquid crystal displaying, and in particular to a TFT (Thin-Film Transistor) array substrate structure.

2. The Related Arts

Liquid crystal displays (LCDs) have a variety of advantages, such as thin device body, low power consumption, and being free of radiation, and are thus widely used, such as mobile phones, personal digital assistants (PDAs), digital cameras, computer monitors, and screens of notebook computers.

A liquid crystal display generally comprises an enclosure, a liquid crystal display panel arranged in the enclosure, and a backlight module mounted in the enclosure. As shown in FIG. 1, a conventional liquid crystal display panel comprises a TFT array substrate 100, a color filter (CF) substrate 300 located above and bonded to the TFT array substrate 100, a liquid crystal layer 500 arranged the array substrate 100 and the CF substrate 300, and a sealant frame 700 and the operation principle thereof is a drive voltage is applied between the TFT array substrate 100 and the CF substrate 300 to control liquid crystal molecules contained in the liquid crystal layer 500 to rotate so as to refract out the light from the backlight module to generate an image.

The liquid crystal display panels that are available in the main stream market can be classified in three categories according to the arrangement of the liquid crystal molecules, which are TN (twisted nematic)/STN (super twisted nematic), IPS (in-plane switching)/FFS (fringe field switching), and VA (Vertical Alignment), wherein the VA type liquid crystal display has advantages, such as high contrast, wide view angle, and excellent color displaying. However, the VA type display uses vertical rotation type liquid crystal, which shows color shift at a large view angle. A known solution for such a phenomenon is to divide a pixel zone into a main zone and a sub zone. Electrical voltage applied to opposite sides of liquid crystal is different for the main zone and the sub zone so that the rotation angle of the liquid crystal in the main zone and the sub zone is different thereby overcoming the color shift problem. As shown in FIG. 2, a TFT array substrate comprises a plurality of sub-pixels 400 arranged to correspond to a black matrix 200. Each of the sub-pixels 400 comprises a main zone 402 and a sub zone 404 corresponding to the black matrix 200. A data line 600 is arranged between the sub-pixels 400 and a gate scan line 800 is arranged between the main zones 402 and the sub zones 404. Pixel electrodes 900 are arranged between the main zones 402 and the sub zones 404 of the sub-pixels and are parallel to the data line 600. The pixel electrodes comprise a main trunk 902 and branches 904.

With the emergence of curved liquid crystal displays, the liquid crystal display panels need to be curved to show a predetermined curvature. During the process of curving, the TFT array substrate and the CF substrate undergo increasingly relative displacement in a horizontal direction towards the left and the right with respect to a reference defined by the center thereof, leading to occurrence of dark patterns in the portions adjacent to the site corresponding to the main trunk of the pixel electrode. It is even worse that the relatively displaced portions of the liquid crystal panel resulting from curving are increasingly enlarged from the reference defined by the center toward the left and the right, leading difference of brightness between the large displacement portions on the left side and the right sides and the displacement-free central portion. In other words, those portions undergoing large displacements have darker brightness, which makes the displaying of the entire panel poor.

### SUMMARY OF THE INVENTION

An object of the present invention is to provide a TFT (Thin-Film Transistor) array substrate structure, in which a pixel electrode trunk is arranged above a data line so as to prevent the occurrence of dark patterns and non-uniform brightness in a displaying process when applied to a curved liquid crystal display panel thereby enhancing the performance of displaying.

To achieve the above object, the present invention provides a TFT array substrate structure, which comprises a plurality of sub-pixels arranged to correspond to a black matrix formed on a color filter substrate. Each of the sub-pixels comprises a main zone and a sub zone corresponding to the black matrix. A data line is arranged between the sub-pixels and a gate scan line is arranged between the main zones and the sub zones. Pixel electrode trunks are arranged between two adjacent ones of the sub-pixels and pixel electrode branches are respectively set in the main zones and the sub zones of the two sub-pixels. The pixel electrode branches are respectively in electrical connection with the pixel electrode trunks.

The pixel electrode trunks are located above the data line.

The pixel electrode trunks have a width that is less than a width of the black matrix between the two sub-pixels.

The pixel electrode branches that are located in the two main zones of the two sub-pixels collectively form an X-shape.

The pixel electrode branches that are located in the two sub zones of the two sub-pixels collectively form an X-shape.

The pixel electrode branches located in the two main zones and the two sub zones of the two sub-pixels collectively form an X-shape.

The pixel electrode trunks and the pixel electrode branches are made of indium tin oxides.

The TFT array substrate structure is used in a vertical alignment type liquid crystal display panel.

The TFT array substrate structure is used in a curved liquid crystal display panel.

The present invention also provides a TFT array substrate structure, which comprises a plurality of sub-pixels arranged to correspond to a black matrix formed on a color filter substrate, each of the sub-pixels comprising a main zone and a sub zone corresponding to the black matrix, a data line being arranged between the sub-pixels and a gate scan line being arranged between the main zones and the sub zones, pixel electrode trunks being arranged between two adjacent ones of the sub-pixels and pixel electrode branches being respectively set in the main zones and the sub zones of the two sub-pixels, the pixel electrode branches being respectively in electrical connection with the pixel electrode trunks;

the pixel electrode trunks being located above the data line;

the pixel electrode trunks having a width that is less than a width of the black matrix between the two sub-pixels;

the pixel electrode branches located in the two main zones and the two sub zones of the two sub-pixels collectively forming an X-shape;

the pixel electrode trunks and the pixel electrode branches being made of indium tin oxides; and

the TFT array substrate structure being used in a vertical alignment type liquid crystal display panel.

The present invention provides a TFT array substrate structure, in which a pixel electrode trunk is arranged on a data line so as to be kept within an area covered by a back matrix in a situation where a relative displacement occurs in a process of curving a liquid crystal display panel thereby effectively improving electric characteristics, preventing the occurrence of dark patterns, and thus enhancing the quality of the liquid crystal display panel.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIG. 1 is a cross-sectional view showing of a conventional liquid crystal display panel;

FIG. 2 is a top plan view showing the structure of a conventional TFT (Thin-Film Transistor) array substrate;

FIGS. 3 is a top plan view showing a TFT array substrate structure according to the present invention; and

FIG. 4 is a top plan view showing a TFT array substrate structure according to another embodiment of the present invention.

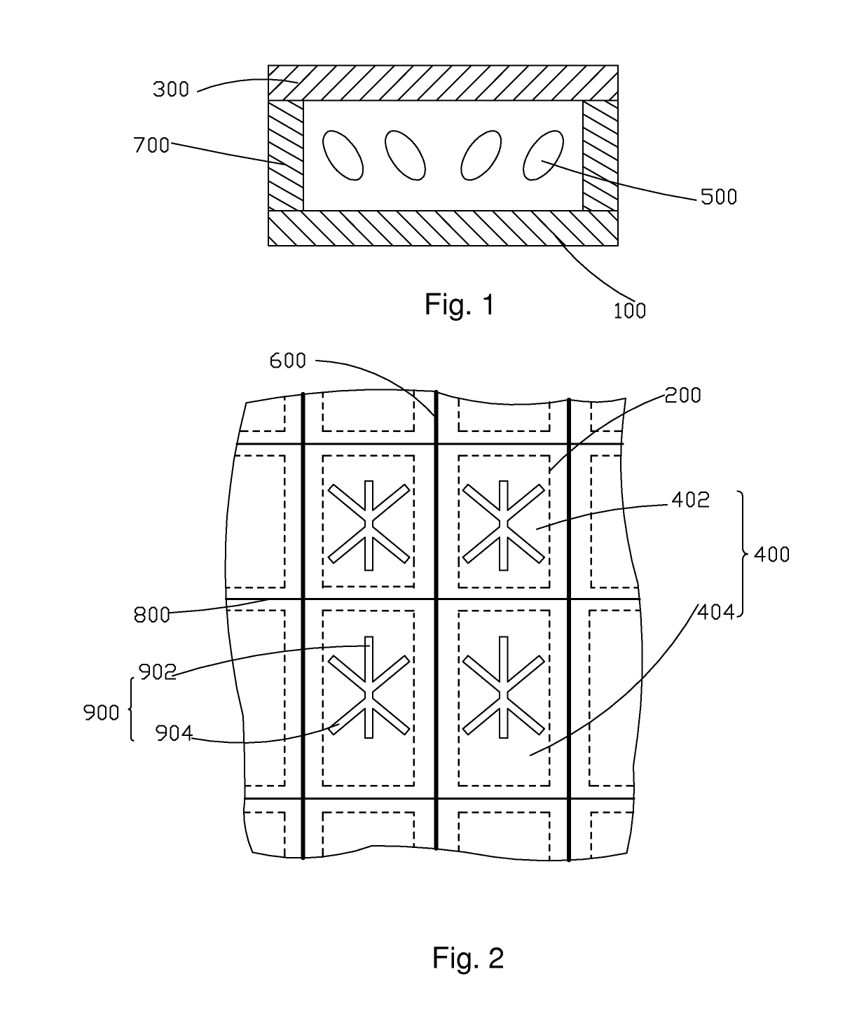

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

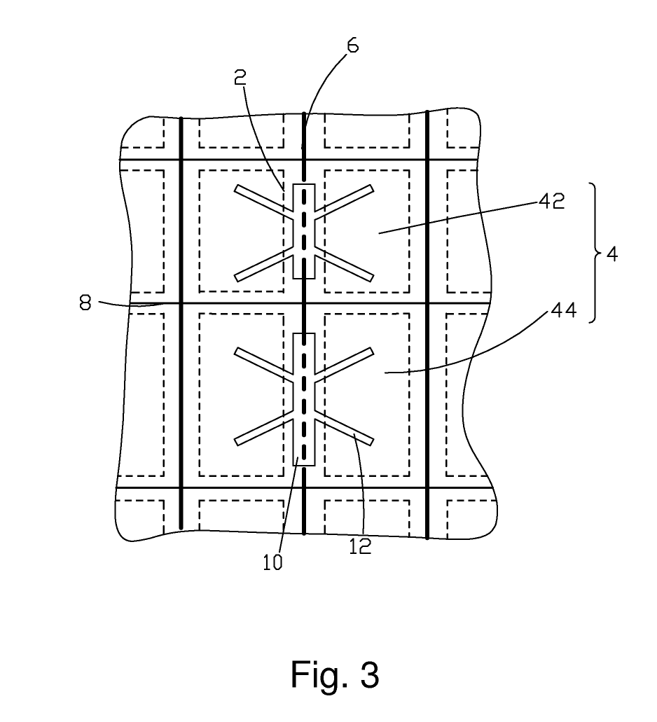

Referring to FIG. 3, the present invention provides a TFT (Thin-Film Transistor) array substrate structure, which comprises: a plurality of sub-pixels 4 arranged to correspond to a black matrix 2 formed on a CF (Color Filter) substrate. Each of the sub-pixels 4 comprises a main zone 42 and a sub zone 44 corresponding to the black matrix 2. A data line 6 is arranged between the sub-pixels and a gate scan line 8 is arranged between the main zones 42 and the sub zones 44. Pixel electrode trunks 10 are arranged between two adjacent ones of the sub-pixels 4 and pixel electrode branches 12 are respectively set in the main zones 42 and the sub zones 44 of the two sub-pixels 4. The pixel electrode branches 12 are respectively in electrical connection with the pixel electrode trunks 10.

The pixel electrode trunks 10 are located above the data line 6 and below the portion of the black matrix 2 between the two sub-pixels 4. The pixel electrode trunks 10 have a width less than a width of the portion of the black matrix 2 between the two sub-pixels 4 so that the pixel electrode trunks 10 are located in an area covered by the black matrix 2. The pixel electrode trunks 10 and the pixel electrode branches 12 are made of indium tin oxides.

The pixel electrode branches 12 that are located in the two main zones 42 of the two sub-pixels 4 collectively form an X-shape and the pixel electrode branches 12 are symmetrically arranged on opposite sides of the pixel electrode trunk 10. The two main zones 42 share the pixel electrode. The pixel electrode branches 12 that are located in the two sub zones 44 of the two sub-pixels 4 collectively form an X-shape and the pixel electrode branches 12 are symmetrically arranged on opposite sides of the pixel electrode trunk 10. The two sub zones 44 share the pixel electrode.

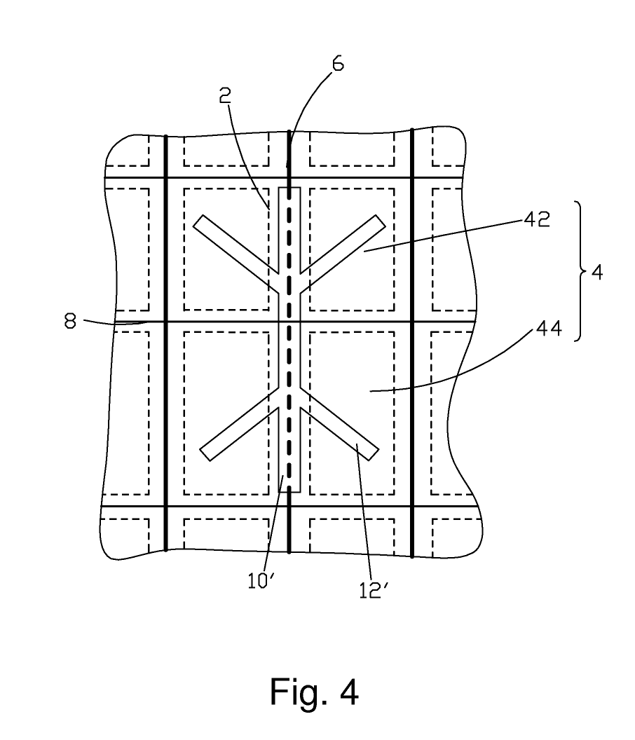

Referring to FIG. 4, which shows another embodiment of the present invention, which is different from the above embodiment in that pixel electrode branches 12′ located in both the two main zones 42 and the two sub zones 44 of the two sub-pixels 4 collectively form an X-shape and the pixel electrode branches 12′ are symmetrically arranged on two sides of a pixel electrode trunk 10′. The two main zones 42 and the two sub zones 44 share the pixel electrode.

In a process of curving a liquid crystal display panel, a TFT array substrate and a CF substrate undergo increasing relative displacement in a horizontal direction, with respect to a reference defined by a center of the panel, toward a left side and a right side, causing a relative displacement of a pixel electrode trunk 10, 10′ formed on the TFT array substrate, but since the pixel electrode trunk 10, 10′ is located above a data line 6 between two sub-pixels 4 and is located below a portion of a black matrix 2 between the two sub-pixels 4 with a width of the pixel electrode trunk 10, 10′ less than a width of the portion of the black matrix 2 between the two sub-pixels 4, whereby after the relative displacement, the pixel electrode trunk 10, 10′ can be still located within an area covered by the black matrix 2 so that an influence on an electrical field is extremely small and the portion of the curved liquid crystal panel corresponding to the pixel electrode trunk 10, 10′ from generating dark patterns, making the brightness of the entirety of the curved liquid crystal display panel close to being consistent and enhancing the quality of displaying. Thus, the TFT array substrate structure of the present invention is applicable to a VA type liquid crystal display panel and the TFT array substrate structure of the present invention is also applicable to a curved liquid crystal display panel and is also applicable to a VA type curved liquid crystal display panel.

In summary, the present invention provides a TFT array substrate structure, in which a pixel electrode trunk is arranged on a data line so as to be kept within an area covered by a back matrix in a situation where a relative displacement occurs in a process of curving a liquid crystal display panel thereby effectively improving electric characteristics, preventing the occurrence of dark patterns, and thus enhancing the quality of the liquid crystal display panel.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A thin-film transistor (TFT) array substrate structure, comprising a plurality of sub-pixels arranged to correspond to a black matrix formed on a color filter substrate, each of the sub-pixels comprising a main zone and a sub zone corresponding to the black matrix, a data line being arranged between the sub-pixels and a gate scan line being arranged between the main zones and the sub zones, pixel electrode trunks being arranged between two adjacent ones of the sub-pixels and pixel electrode branches being respectively set in the main zones and the sub zones of the two sub-pixels, the pixel electrode branches being respectively in electrical connection with the pixel electrode trunks.

2. The TFT array substrate structure as claimed in claim 1, wherein the pixel electrode trunks are located above the data line.

3. The TFT array substrate structure as claimed in claim 1, wherein the pixel electrode trunks have a width that is less than a width of the black matrix between the two sub-pixels.

4. The TFT array substrate structure as claimed in claim 1, wherein the pixel electrode branches that are located in the two main zones of the two sub-pixels collectively form an X-shape.

5. The TFT array substrate structure as claimed in claim 1, wherein the pixel electrode branches that are located in the two sub zones of the two sub-pixels collectively form an X-shape.

6. The TFT array substrate structure as claimed in claim 1, wherein the pixel electrode branches located in the two main zones and the two sub zones of the two sub-pixels collectively form an X-shape.

7. The TFT array substrate structure as claimed in claim 1, wherein the pixel electrode trunks and the pixel electrode branches are made of indium tin oxides.

8. The TFT array substrate structure as claimed in claim 1, wherein the TFT array substrate structure is used in a vertical alignment type liquid crystal display panel.

9. The TFT array substrate structure as claimed in claim 1, wherein the TFT array substrate structure is used in a curved liquid crystal display panel.

10. A thin-film transistor (TFT) array substrate structure, comprising a plurality of sub-pixels arranged to correspond to a black matrix formed on a color filter substrate, each of the sub-pixels comprising a main zone and a sub zone corresponding to the black matrix, a data line being arranged between the sub-pixels and a gate scan line being arranged between the main zones and the sub zones, pixel electrode trunks being arranged between two adjacent ones of the sub-pixels and pixel electrode branches being respectively set in the main zones and the sub zones of the two sub-pixels, the pixel electrode branches being respectively in electrical connection with the pixel electrode trunks;
wherein the pixel electrode trunks are located above the data line;
wherein the pixel electrode trunks have a width that is less than a width of the black matrix between the two sub-pixels;
wherein the pixel electrode branches located in the two main zones and the two sub zones of the two sub-pixels collectively form an X-shape;
wherein the pixel electrode trunks and the pixel electrode branches are made of indium tin oxides; and
wherein the TFT array substrate structure is used in a vertical alignment type liquid crystal display panel.
